(19) United States
(12) Patent Application Publication
(10) Pub. No.: US 2009/0032881 A1
(43) Pub. Date: Feb. 5, 2009

(54) SEMICONDUCTOR DEVICES AND METHODS OF FABRICATING THE SAME IN WHICH A MOBILITY CHANGE OF THE MAJOR CARRIER IS INDUCED THROUGH STRESS APPLIED TO THE CHANNEL

(75) Inventors: Joo-Won Lee, Gyeonggi-do (KR); Dong-Suk Shin, Gyeonggi-do (KR); Tae-Gyun Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/165,999

(22) Filed: Jul. 1, 2008

(30) Foreign Application Priority Data
Jul. 30, 2007 (KR) 10-2007-0076505

(51) Int. Cl. H01L 27/118; H01L 21/8238

(52) U.S. Cl. 257/369; 438/199; 257/E27.108; 257/E21.632

(57) ABSTRACT

A semiconductor device includes a semiconductor substrate, a gate structure formed on the semiconductor substrate, wherein the gate structure includes a gate electrode formed on the semiconductor substrate and spacers formed on sidewalls of the gate electrode, source/drain regions formed in the semiconductor substrate on both sides of the gate structure, and an etch stop layer, which is formed on the gate structure, and includes a first region formed on the spacers and a second region formed on the gate electrode, wherein the thickness of the first region is about 85% that of the thickness of the second region or less.

### CROSS REFERENCE TO RELATED APPLICATION

This application claims priority to Korean Patent Application No. 10-2007-0076505 filed on Jul. 30, 2007 in the Korean Intellectual Property Office, the disclosure of which is incorporated herein by reference in its entirety.

### BACKGROUND OF THE INVENTION

1. Field of the Invention

The present invention relates to semiconductor devices and methods of manufacturing the same. More particularly, the present invention relates to semiconductor devices having a transistor channel to which stress is applied, and methods of manufacturing the same to produce stress in the transistor channel.

2. Description of the Related Art

Research has been carried out to develop various methods to overcome the density and speed limitations of semiconductor devices, and to develop high performance MOS transistors. In particular, methods to implement high performance MOS transistors to increase mobility of major carriers (electron or hole) have been developed.

To increase the mobility of electrons or holes, methods to apply physical stress to channel region have been investigated. As a representative example, a stress layer is formed on a MOS transistor. However, because electrons and holes show different mobilities depending on the type of stress, such as tensile stress and compressive stress, a stress layer used to increase mobility of electron in a NMOS transistor does not necessarily increase mobility of holes in a PMOS transistor. Therefore, methods to apply separate stress to NMOS transistors and PMOS transistors have been investigated.

### SUMMARY

According to some embodiments of the present invention, there is provided a semiconductor device including a semiconductor substrate and a gate structure formed on the semiconductor substrate, wherein the gate structure includes a gate electrode formed on the semiconductor substrate and spacers formed on sidewalls of the gate electrode. Source/drain regions are formed in the semiconductor substrate on both sides of the gate structure. An etch stop layer is formed on the gate structure and includes a first region formed on the spacers and a second region formed on the gate electrode, wherein the thickness of the first region is about 85% that of the thickness of the second region or less.

According to other embodiments of the present invention, there is provided a semiconductor device including a semiconductor substrate including an NMOS transistor region and a PMOS transistor region, a first gate structure formed in the NMOS transistor region on the semiconductor substrate, wherein the first gate structure includes a first gate electrode formed on the semiconductor substrate and first spacers formed on sidewalls of the first gate electrode, first source/drain regions formed in the semiconductor substrate on both sides of the first gate structure, a second gate structure formed in the PMOS transistor region on the semiconductor substrate, wherein the second gate structure includes a second gate electrode formed on the semiconductor substrate and second spacers formed on sidewalls of the second gate electrode, second source/drain regions formed in the semiconductor substrate on both sides of the second gate structure, and an etch stop layer, which is formed on the first gate structure and the second gate structure and includes a first region formed on the first spacers and the second spacers and a second region formed on the first gate electrode and the second gate electrode, wherein the thickness of the first region is about 85% that of the thickness of the second region or less.

According to still other embodiments of the present invention, there is provided a method of fabricating a semiconductor device, including providing a semiconductor substrate, forming a gate structure on the semiconductor substrate, wherein the gate structure includes a gate electrode formed on the semiconductor substrate and spacers formed on sidewalls of the gate electrode, forming source/drain regions on both sides of the gate structure, forming an etch stop layer on the gate structure that includes a first region formed on the spacers and a second region formed on the gate electrode, wherein the thickness of the first region is about 85% of the thickness of the second region or less, and forming a tensile stress layer on the etch stop layer.

According to still other embodiments of the present invention, there is provided a method of fabricating a semiconductor device, including providing a semiconductor substrate including an NMOS transistor region and a PMOS transistor region, forming a first gate structure in the NMOS transistor region on the semiconductor substrate, wherein the first gate structure includes a first gate electrode formed on the semiconductor substrate and first spacers formed on sidewalls of the first gate electrode and a second gate structure in the PMOS transistor region on the semiconductor substrate, wherein the second gate structure includes a second gate electrode formed on the semiconductor substrate and second spacers formed on sidewalls of the second gate electrode, forming first source/drain regions on both sides of the first gate structure and second source/drain regions on both sides of the second gate structure, forming an etch stop layer on the first gate structure and the second gate structure that includes a first region formed on the first spacers and the second spacers and a second region formed on the first gate electrode and the second gate electrode, wherein the thickness of the first region is about 85% of the thickness of the second region or less, and forming a tensile stress layer on the etch stop layer.

### BRIEF DESCRIPTION OF THE DRAWINGS

The above and other features and advantages of the present invention will become apparent by describing in detail exemplary embodiments thereof with reference to the attached drawings in which:

FIG. 1 is a sectional view illustrating a semiconductor device according to some embodiments of the present invention;

FIG. 2 is a perspective view illustrating a semiconductor device according to some embodiments of the present invention;

FIG. 3 is a sectional view illustrating a semiconductor device according to further embodiments of the present invention;

FIG. 4 is a sectional view illustrating a semiconductor device according to still further embodiments of the present invention;

FIG. 5 is a graph illustrating the relative values of stress when an etch stop layer is placed between a stress layer and a MOS transistor;

FIGS. 6A through 6H are sectional views sequentially illustrating methods of fabricating a semiconductor device according to some embodiments of the present invention;

FIGS. 7A through 7B are sectional views sequentially illustrating methods of fabricating a semiconductor device according to further embodiments of the present invention; and

FIGS. 8A through 8D are sectional views sequentially illustrating methods of fabricating a semiconductor device according to still further embodiments of the present invention.

### DETAILED DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

Semiconductor devices according to some embodiments of the present invention include a MOS transistor having a mobility change of the major carrier due to the stress applied to a channel. The MOS transistor may be an NMOS transistor or a PMOS transistor in accordance with various embodiments of the present invention.

For example, when applying a tensile stress layer, the stress layer can be selectively formed on an NMOS transistor. In this case, the tensile stress layer on a PMOS transistor can be selectively removed. To perform an accurate patterning to remove the tensile stress layer selectively, an etch stop layer can be formed before forming the tensile stress layer. However, if an etch stop layer is placed between the NMOS transistor and the tensile stress layer as a result of forming an etch stop layer, the stress effect introduced from the tensile stress layer to the NMOS transistor may be decreased. Thus, significant improvement of the electron mobility may not be achieved.

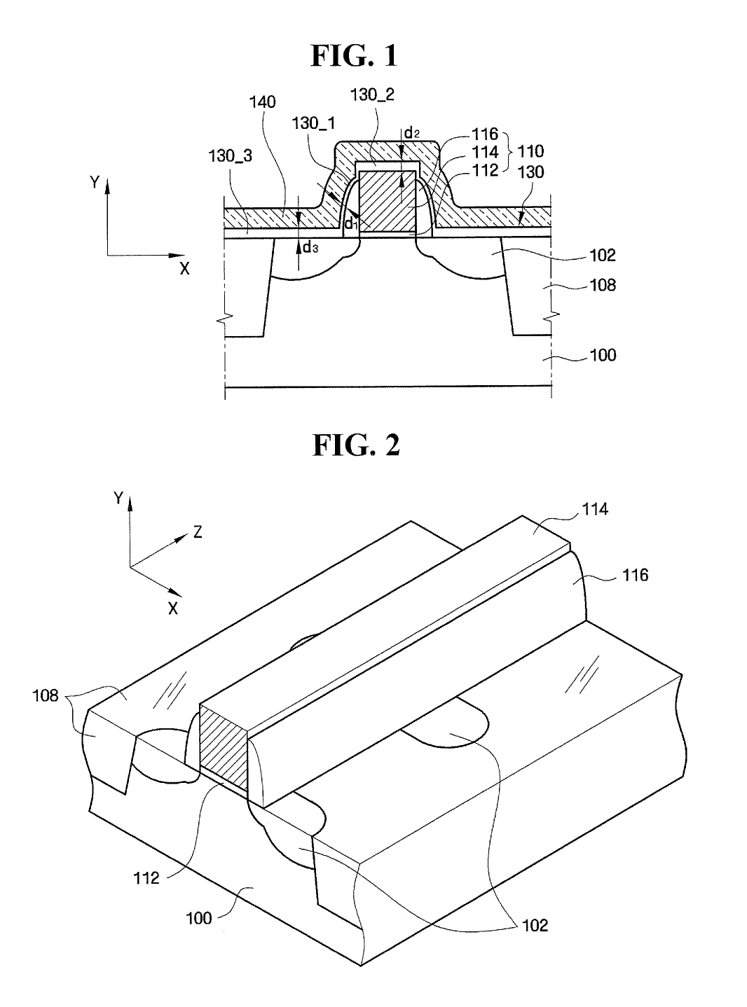

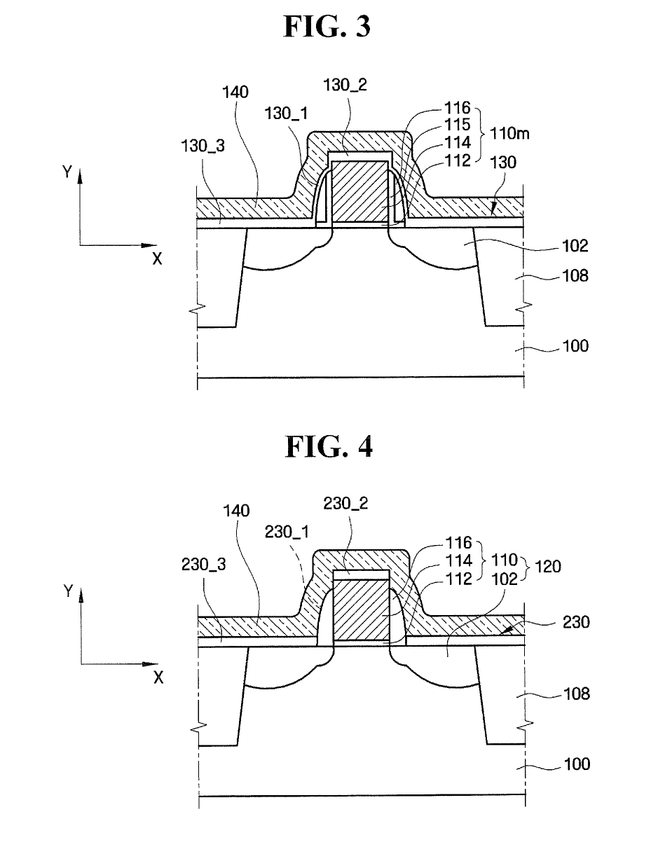

FIG. 1 is a sectional view illustrating a semiconductor device according to some embodiments of the present invention. FIG. 2 is a perspective view illustrating a semiconductor device according to some embodiments of the present invention, including an etch stop layer and a stress layer, which are not shown in FIG. 1. FIG. 3 and FIG. 4 are sectional views illustrating a semiconductor device according to further embodiments of the present invention.

Referring to FIGS. 1 and 2, a semiconductor device according to some embodiments of the present invention includes a MOS transistor formed on a semiconductor substrate 100. The MOS transistor includes a gate structure 110 and source/drain regions 102.

The gate structure 110 includes a gate dielectric layer 112 formed on the semiconductor substrate 100, a gate electrode 114 formed on the gate dielectric layer 112, and a spacer 116 formed on a sidewall of the gate electrode 114.The gate dielectric layer 112 can be formed of a silicon oxide layer and/or a high-k layer.

The gate electrode 114 may be formed of a conductive material. For example, the gate electrode 114 can be formed of a single layer of an n-type or p-type doped polysilicon layer, a metal layer, a metal silicide layer, a metal nitride layer, and/or a layer stacked with combinations of these layers.

The gate electrode 114 according to some embodiments of the present invention is formed of a polysilicon layer, which includes an n-type or a p-type impurity as well as amorphization material. The amorphization material can be an ion implanted material. Examples of an implanted amorphization material include Ge, Xe, C, and/or F. The polysilicon layer that forms the gate electrode 114 according to some embodiments of the present invention is amorphized by the implantation of the amorphization material, and is recrystallized by a subsequent thermal treatment. During the recrystallization, the polysilicon stores predetermined stress depending on the state change of the recrystallization, and this can provide predetermined stress to a channel of the MOS transistor.

The gate electrode 114 according to further embodiments of the present invention does not include an amorphized material. In this case, the stress introduced to the MOS transistor is caused by a remaining stress layer 140, which covers the MOS transistor. Therefore, an amorphization material in the gate electrode 114 may have a close relationship with the stress layer 140 to provide a channel with stress.

The spacers 116 are formed on sides of the gate electrode 114. The spacer 116 can be formed of silicon nitride. Although not shown in the drawings, a hard mask layer can be formed on the gate electrode 114.

In the further embodiments of the present invention illustrated in FIG. 3, a gate structure 110m can include a natural oxide layer 115 formed between the spacer 116 and the gate electrode 114. In still further embodiments of the present invention, the natural oxide layer 115 in FIG. 3 can be replaced with an L-type spacer.

Referring to FIGS. 1 and 2, the source/drain regions 102 are formed by doping n-type or p-type impurities into the semiconductor substrate 100 of both sides of the gate structure 110. Depending on the conductive type of the doped impurity, a MOS transistor can be an NMOS transistor or a PMOS transistor. Although not shown in FIG. 1, the top surface of the source/drain region 102 according to some embodiments of the present invention can be formed of metal silicide.

Similar to the gate electrode 114, the source/drain regions 102 can include additional amorphization material. The space between the source/drain regions 102, which are separated by the gate structure 110, becomes a channel region of the MOS transistor. The outside of the source/drain regions 102 is restricted by a device-isolation region 108 formed in the semiconductor device 100. For example, the device-isolation region 108 can be formed of an oxide layer formed by a STI (Shallow Trench Isolation) process or a LOCOS (LOCal Oxidation of Silicon) process.

An etch stop layer 130 is located on the semiconductor substrate 100, which the gate structure 110 is formed on. The etch stop layer 130 covers the gate structure 110 and the source/drain regions 102.

The etch stop layer 130 includes a first region 130_1, which is located on the spacers 116 of the gate structure 110, a second region 130_2, which is located on the top surface of the gate electrode 114, and a third region 130_3, which is located on the source/drain regions 102. The etch stop layer 130 can be formed of silicon oxide.

The stress layer 140 is formed on the etch stop layer 130 and provides the MOS transistor channel with tensile stress or compressive stress. The stress layer 140 can be formed of silicon nitride layer, and a silicon nitride layer can be a tensile stress layer or a compressive stress layer depending on the composition ratio of silicon, nitrogen, and hydrogen as well as the process conditions during fabrication.

In some embodiments in which the gate electrode 114 and the source/drain regions 102 include the amorphization material, the stress layer 140 can be removed. In other embodiments in which the gate electrode 114 and the source/drain regions 102 do not include the amorphization material, it may be desirable to have the stress layer 140.

The stress applied to the MOS transistor channel may increase the mobility of a major carrier that flows through the channel depending on the type of the MOS transistor, the type of stress, and the direction of stress. When the mobility of the major carrier is increased, the performance of the MOS transistor improves. Detailed relationships among the variables described above are summarized in Table 1.

TABLE 1
Mobility of the major carrier in MOS transistor

| | | | MOBILITY OF | MOBILITY OF |
|---|---|---|---|---|
| | | | MAJOR CARRIER | MAJOR CARRIER |
| STRESS LAYER | STRESS | | (NMOS | (PMOS |
| TYPE | DIRECTION | STRESS TYPE | TRANSISTOR) | TRANSISTOR) |
| TENSILE | X-AXIS | TENSILE | + | −− |
| STRESS LAYER | | STRESS | | |
| | Y-AXIS | COMPRESSIVE | ++ | − |
| | | STRESS | | |
| | Z-AXIS | TENSILE | + | + |
| | | STRESS | | |
| COMPRESSIVE | X-AXIS | COMPRESSIVE | − | ++ |
| STRESS LAYER | | STRESS | | |
| | Y-AXIS | TENSILE | −− | + |
| | | STRESS | | |
| | Z-AXIS | COMPRESSIVE | − | − |
| | | STRESS | | |

The x-axis, y-axis, and z-axis shown in Table 1 represent the 3-dimensional directions defined in FIG. 2. Also, “+” indicates the mobility of the major carrier in a good state, and “++” indicates the mobility of the major carrier in a very good state. In contrast, “−” indicates the mobility of the major carrier in a poor state, and “−” indicates the mobility of the major carrier in a very poor state.

Referring to Table 1, the tensile stress layer provides tensile stress in the directions of the x- and z-axis, but it provides compressive stress in the direction of the y-axis. Also, the compressive stress layer provides compressive stress in the directions of the x- and z-axis, and in the direction of the y-axis. As shown in Table 1, in the case of the NMOS transistor the mobility of the major carrier (electron) is increased by compressive stress in the direction of the y-axis. In the case of the PMOS transistor, the mobility of the major carrier (hole) is increased by compressive stress in the direction of the x-axis.

Such stress used to increase the mobility of the major carrier can be introduced by the stress layer 140 that covers the MOS transistors (for example, in the case of the NMOS transistor the compressive stress in the direction of the y-axis can be introduced by the tensile stress layer, and in the case of the PMOS transistor compressive stress in the direction of the x-axis can be introduced by the compressive stress layer. The gate electrode 114 includes amorphization material and stress is stored during recrystallization. The stress layer 140 does not remain in the final structure, but stress is applied at least during the recrystallization by placement of the stress layer 140.

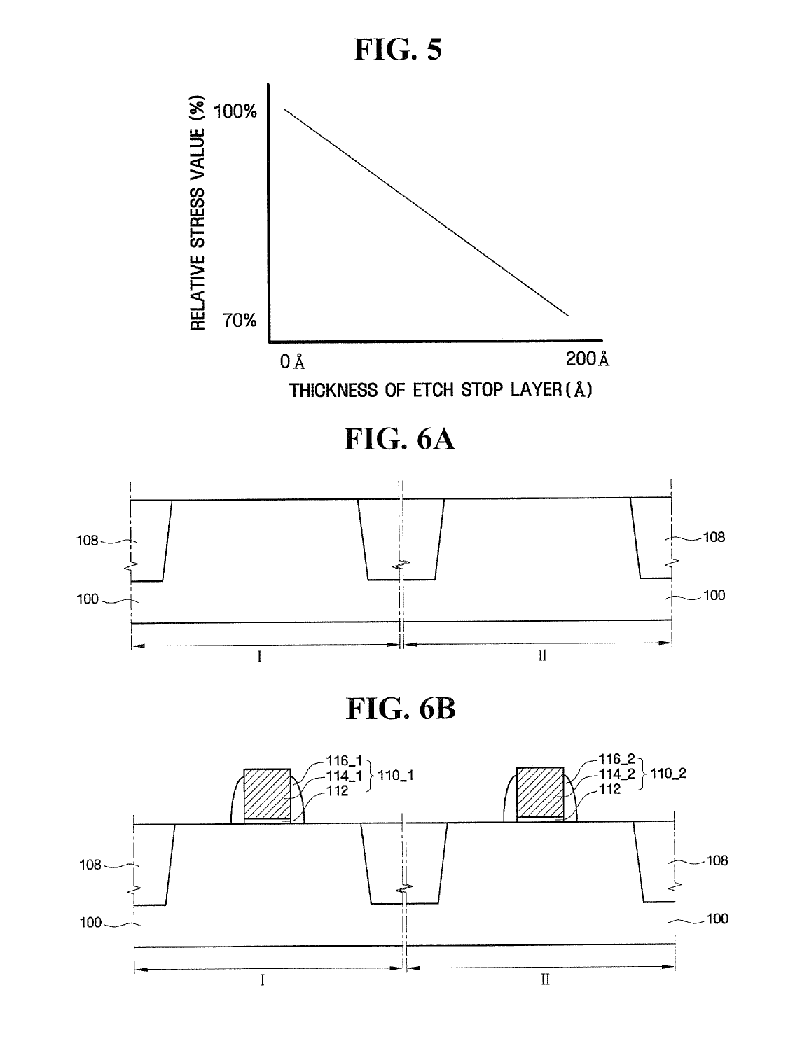

FIG. 5 is a graph illustrating the relative values of stress when an etch stop layer is placed between a stress layer and a MOS transistor. The stress effect by the stress layer 140 partially depends on the closeness or the distance between the stress layer 140 and the location where the stress is introduced. For example, if the stress layer 140 does not have direct contact with the MOS transistor and another structure is placed in between them, the stress effect is decreased. The more thickness the structure placed between them has, the less the stress effect takes place. As illustrated in the graph of FIG. 5 when the thickness of the etch stop layer 130 is about 200 Å, the stress effect becomes about 70% of the stress effect when no etch stop layer 130 exists.

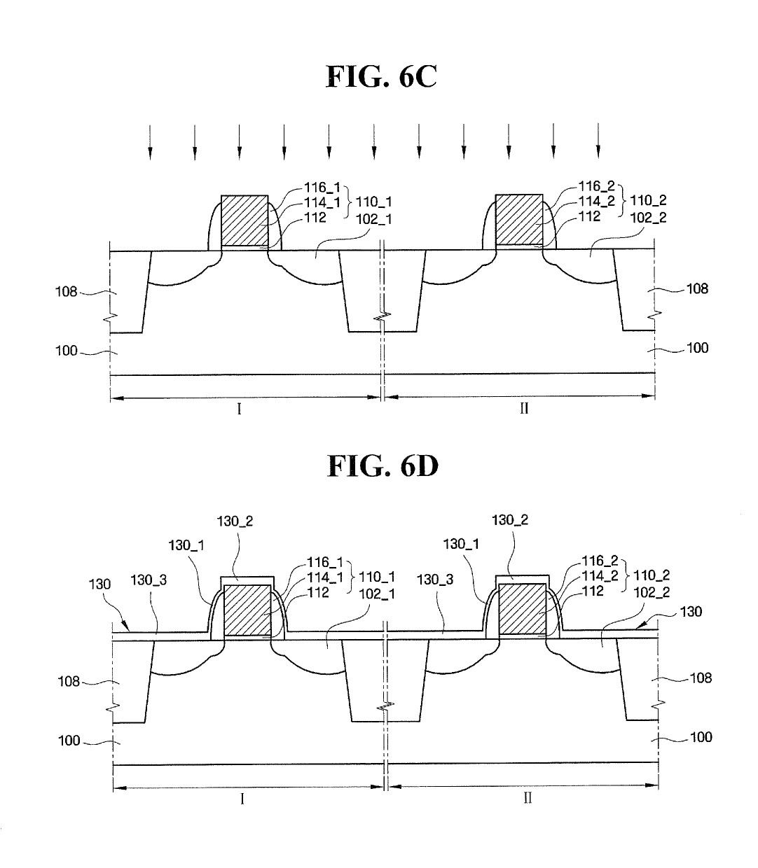

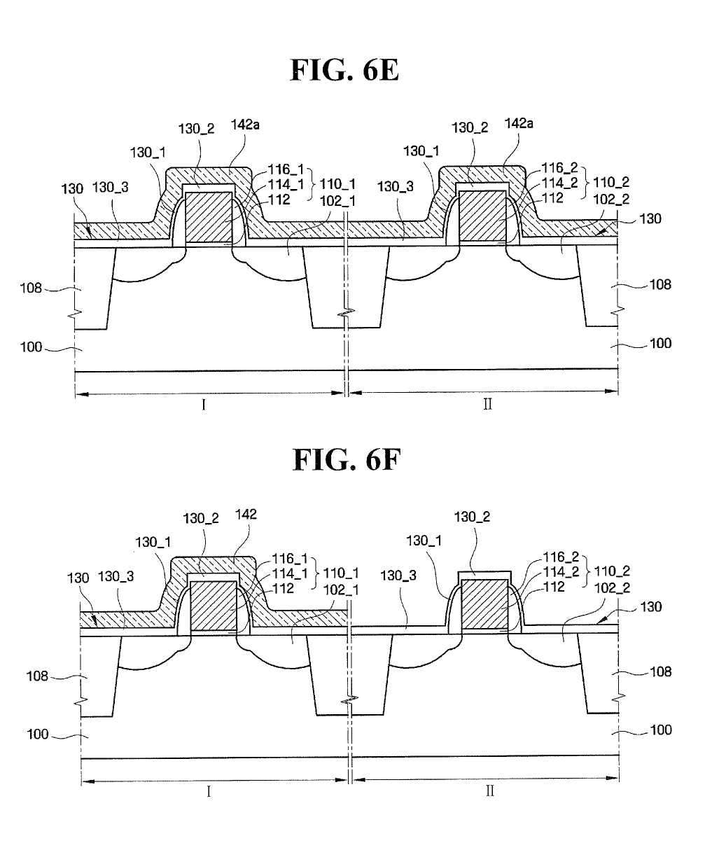

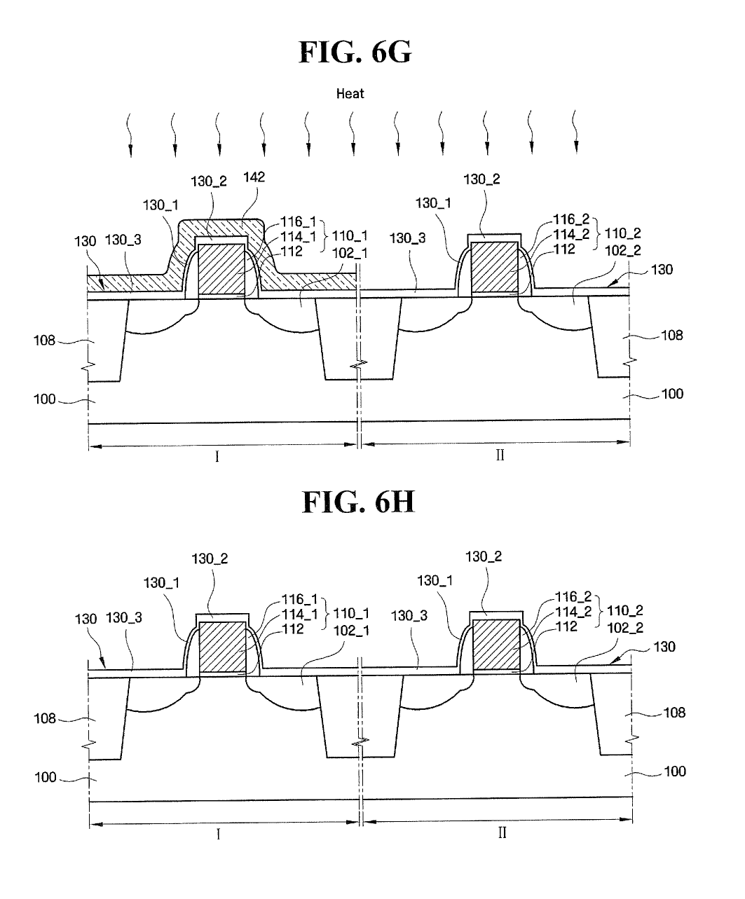

FIGS. 6A through 6H are sectional views sequentially illustrating methods of fabricating a semiconductor device according to some embodiments of the present invention.

In an example where a NMOS transistor is used as a MOS transistor, to obtain sufficient electron mobility, sufficient compressive stress may be introduced in the direction of the y-axis. To achieve this, the thickness of the etch stop layer 130 needs to be small in the region where the stress is applied in the direction of y-axis.

Referring to FIG. 1, in the region where the stress is introduced in the direction of the y-axis, the spacer 116 is formed. Thus, the thickness of a first region 130_1 of the etch stop layer 130, which is formed on the spacer 116, may be relatively small.

The etch stop layer 130 is formed to prevent or reduce excessive etch of the lower structure during processes including the patterning of the stress layer 140. Specifically, a second region 130_2 is the place where the contact formed on the gate electrode 114 is formed, and a third region 130_3 is the place where the contact formed on the source/drain regions 102 is formed. Therefore, to secure the functionality of the etch stop layer 130, an adequate thickness of the second region 130_2 and the third region 130_3 is needed. For example, the thickness of the second region 130_2 and the third region 130_3 can be about 50 Å to about 1000 Å. According to other exemplary embodiments of the present invention, the thickness of the second region 130_2 and the third region 130_3 can be in the range of about 300 Å to about 500 Å.

In contrast, the first region 130_1 is generally not related to the functionality of the etch stop layer 130 since that region has no contacts to be formed and no patterning boundaries. Therefore, the first region 130_1 of the etch stop layer 130 can be formed of smaller thickness than the thickness of the second region 130_2 and the third region 130_3.

Based on the descriptions above, the thickness of the second region 130_2 of the etch stop layer 130 is approximately identical to the thickness of the third region 130_3, and the thickness of the first region 130_1 can be smaller than the thickness of the second region 130_2 and the third region 130_3. For example, the thickness d1 of the first region 130_1 can be less than about 85% of the thicknesses d2 and d3 of the second region 130_2 and the third region 130_3, respectively. Furthermore, the thickness d1 of the first region 130_1 can be less than about 75% of the thicknesses d2 and d3 of the second region 130_2 and the third region 130_3, respectively. In an extreme case, the thickness d1 of a certain part of the first region 130_1 can be 0. Thus, as illustrated in FIG. 4, on the spacer 116, at least part of an etch stop layer 230 may not be formed, or can be removed after formation, which results in direct contact between the spacer 116 and the stress layer 140. According to the exemplary embodiments illustrated in FIG. 4, although the second region 230_2 and the third region 230_3 have certain thickness, the mobility of the major carrier of a NMOS transistor can be most improved if the thickness of the first region 230_1 of the etch stop layer 230 becomes 0 as illustrated in FIG. 5.

Different thicknesses of the etch stop layer 130 in the different regions can be implemented using a stack method, an isotropic etch, and combinations of these methods. As illustrated in FIG. 1, the second region 130_2 and the third region 130_3 of the etch stop layer 130 are formed on a flat lower structure, and the first region 130_1 is formed on the spacer 116 having a slope. If the etch stop layer 130 is deposited using a deposition method having poor step coverage such as PECVD (Plasma Enhanced Chemical Vapor Deposition), the first region 130_1 having a slope can be deposited with a relatively smaller thickness. Based on the descriptions above, the etch stop layer 130 can be formed of a PE-TEOS (TetraEthyl OrthoSilicate) layer. Also, if the etch stop layer 130 is isotropically etched, it is etched with substantially an identical thickness on the entire region. As a result, the ratio of the thickness of the first region 130_1 to the thickness of the second region 130_2 as well as the ratio of the thickness of the first region 130_1 to the thickness of the third region 130_3 can be further decreased. Moreover, as illustrated in FIG. 4, the first region 230_1 of the etch stop layer 230 can be removed completely (in the case of thickness of zero).

More detailed descriptions of a semiconductor device according to exemplary embodiments of the present invention and other exemplary embodiments are presented with reference to the following method of fabricating a semiconductor device according to some embodiments of the present invention. As discussed hereinafter, an example of semiconductor device includes an NMOS transistor and a PMOS transistor.

FIGS. 6A through 6H are sectional views illustrating methods of fabricating a semiconductor device including stress memorization techniques according to some embodiments of the present invention.

Referring to FIG. 6A, a semiconductor substrate 100 including an NMOS transistor region I and a PMOS transistor region II is provided. The semiconductor substrate 100 is formed of crystalline silicon, such as single-crystalline silicon, for example, p-type silicon substrate doped with p-type impurities.

In the NMOS transistor region I, an NMOS transistor is formed, and n-type impurities are doped in the active region. In a PMOS transistor region II, a PMOS transistor is formed, and P-type impurities are doped in the active region. When the semiconductor substrate 100 is initially provided, the NMOS transistor region I and the PMOS transistor region II are not physically divided. However, the semiconductor substrate 100 can have a virtual boundary based on the designed successive processes. The NMOS transistor region I and the PMOS transistor region can be more clearly divided by the transistor type formed during the successive processes.

Next, a device-isolation region 108 is formed to divide the semiconductor substrate 100 into several active regions. The device-isolation region 108, for example, can be formed of a silicon oxide layer. In more detail, a STI oxide layer using STI (Shallow Trench Isolation) process or a LOCOS oxide layer using LOCOS (LOCal Oxidation of Silicon) process can be used to form the device-isolation region 108.

Referring to FIG. 6B, an oxide layer for gate dielectric layer is formed using a thermal oxidation process on the entire semiconductor substrate 100. Then, a gate conducting layer composed of crystalline silicon including polysilicon or amorphous silicon is formed on the oxide layer serving as the gate dielectric layer. Formation of the gate conducting layer can be done using various methods in accordance with various embodiments of the present invention. Next, the gate conducting layer and the oxide layer serving as the gate dielectric layer are sequentially patterned, and gate electrodes 114_1, 114_2 and a gate dielectric layer 112 are formed. A photoresist layer or a hard mask layer can be used as an etch mask for the patterning described above. Here, the gate electrode formed on the NMOS transistor region I of the semiconductor substrate 100 is called a first gate electrode 114_1, and the gate electrode formed on the PMOS transistor region II of the semiconductor substrate 100 is called a second gate electrode 114_2.

Then, a first spacer 116_1 is formed on the sidewall of the first gate electrode 114_1, and a second spacer 116_2 is formed on the sidewall of the second gate electrode 114_2. The first spacer 116_1 and the second spacer 116_2 may be formed of a silicon nitride layer. A first gate structure 110_1 includes the first spacer 116_1, the first gate electrode 114_1, and the gate dielectric layer 112, and a second gate structure 110_2 includes the second spacer 116_2, the second gate electrode 114_2, and the gate dielectric layer 112.

Referring to FIG. 6C, first impurities are ion-implanted using a first ion mask (not shown) to cover the PMOS transistor region II and to expose the NMOS transistor region I of the semiconductor substrate 100. The first impurities include N-type impurities and amorphization material.

The N-type impurities are used to form source/drain regions 102_1 in the semiconductor substrate 100 of the NMOS transistor region I. Since the N-type impurities are implanted in the NMOS transistor region I of the semiconductor substrate 100 not covered by the first ion mask, they can be partially implanted into the first gate electrode 114_1 and the first spacer 116_1. However, from the semiconductor substrate 100 point of view, the first gate electrode 114_1 and the first spacer 116_1 as well as the first ion mask are considered as a doping mask. As s result, the N-type impurities are not implanted underneath the first gate electrode 114_1. Therefore, a pair of source/drain regions 102_1 separated from each other by the first gate electrode 114_1 is formed in the semiconductor substrate 100 of the NMOS transistor region I.

Amorphization material is used to amorphize the semiconductor substrate 100 and/or the first gate electrode 114_1 of the NMOS transistor region I. Although the semiconductor substrate 100 and the first gate electrode 114_1 are composed of crystalline silicon, ion implantation of amorphization material causes amorphization due to destruction of crystal. Examples of the amorphization ions include Ge, Xe, C, and/or F.

The order of ion implantation of the N-type impurities and the amorphization material can be selected in several ways. For example, after the N-type impurities are ion implanted to form the first source/drain regions 102_1, these regions can be amorphized by ion implantation of the amorphization material. Also, after ion implantation of the amorphization material is performed to define an amorphization region, the N-type impurities can be ion implanted to form the amorphized first source/drain 102_1 regions.

Next, second impurities are ion implanted using a second ion mask (not shown) to cover the NMOS transistor region I and to expose the PMOS transistor region II of the semiconductor substrate 100. The second impurities include P-type impurities and amorphization material. The ion implantation of the second impurities is substantially identical to the ion implantation of the first impurity except that P-type impurities, instead of the N-type impurities, are ion implanted. As a result, a pair of second source/drain regions 102_2 separated from each other by the second gate electrode 114_2 is formed in the semiconductor substrate 100 of the PMOS transistor region II, and the second electrode 114_2 and the second source/drain regions 102_2 are amorphized.

The ion implantation of the first impurities and the ion implantation of the second impurities can be in reverse order to that described above in accordance with other embodiments of the present invention.

Also, amorphization material can be ion implanted in both of the NMOS transistor region I and the PMOS transistor region II at the same time before or after the ion implantation of the N-type impurity and the P-type impurity. In this case, an additional ion mask is not required.

Referring to FIG. 6D, an etch stop layer 130 is formed on the entire surface of the structure of FIG. 6C. The etch stop layer 130 is formed to cover the first gate structure 110_1, the first source/drain regions 102_1, the second gate structure 110_2, and the second source/drain regions 102_2. The etch stop layer 130 includes a first region 130_1 on the first and the second spacers 116_1, 116_2 and a second region 130_2 on the first and the second gate electrodes 114_1, 114_2, and a third region 130_3 on the first and the second source/drain regions 102_1, 102_2. The thickness of the second region 130_2 may be substantially identical to the thickness of the third region 130_3, but the first region 130_1 is formed to have a smaller thickness than the thickness of the second region 130_2 and the third region 130_3. For example, the second region 130_2 and the third region 130_3 are formed to have a thickness in the range of about 50 Å to about 1000 Å. According to other exemplary embodiments of the present invention, the second region 130_2 and the third region 130_3 are formed to have a thickness in the range of about 100 Å to about 500 Å. The first region 130_1 is formed to have a thickness that is about 85% that of the thickness of the second region 130_2 and the third region 130_3. According to some embodiments of the present invention, the first region 130_1 is formed to have a thickness that is about 75% that of the thickness of the second region 130_2 and the third region 130_3.

To form the etch stop layer 130 having different thicknesses in different regions, a stacking method having generally poor step coverage is used. The lower structure where the second region 130_2 and the third region 130_3 are placed has a relatively flat surface, but the lower structure (the first spacer and the second spacer) where the first region 130_1 is placed has a tilted surface. Thus, if the etch stop layer 130 is formed using a method having generally poor step coverage, the thickness of the etch stop layer deposited on the first and the second spacers 116_2 can be less than the thickness of the etch stop layer in other regions. For example, if the etch stop layer 130 is formed of a PE-TEOS layer using plasma enhanced chemical vapor deposition, the thickness of the first region 130_1 can be controlled to have less than about 85%, or even about 75%, of the thickness of the second region 130_2 and the third region 130_3.

Referring to FIG. 6E, a tensile stress layer 142a is formed on the etch stop layer 130 as a cover layer. The tensile stress layer 142 is formed of silicon nitride.

Referring to FIG. 6F, the tensile stress layer 142a on the PMOS transistor region II is selectively removed to only have the tensile stress layer on the NMOS transistor region I. The tensile stress layer 142a is selectively removed using a photo etch process, and in this step the etch stop layer 130 provides etch-stopping capability to prevent or reduce the likelihood of over-etching lower structures.

Referring to FIG. 6G, the resulting structure shown in FIG. 6F is processed thermally. In a specific example, in an atmosphere of nitrogen, argon, hydrogen or mixture of these materials, rapid thermal treatment is performed at a temperature between about 900° C. and about 1200° C. As a result of the thermal treatment, recrystallization in the amorphized region occurs. Thus, even though the first gate electrode 114_1, the first source/drain regions 102_1, the second gate electrode 114_2, and the second source/drain regions 102_2 are amorphized by ion implantation of the amorphization material described above, they are recrystallized, for example, as a polysilicon.

Due to recrystallization, stress caused by the tensile stress layer 142 is stored in the first gate electrode 114_1 and the first source/drain regions 102_1 on the NMOS transistor region I. Because the NMOS transistor region I is covered by the tensile stress layer 142, a tensile stress is introduced in the direction of the x-axis and the z-axis and a compressive stress is introduced in the direction of the y-axis. Therefore, the first gate electrode 114_1 and the first source/drain regions 102_1 on the NMOS transistor region I are recrystallized with the memory of tensile stress in the direction of the x-axis and the z-axis and the compressive stress in the direction of the y-axis caused by the tensile stress layer 142. Here, although the first gate electrode 114_1 receives stress due to the tensile stress layer 142 by placement of the etch stop layer 130, the stress decrease by placing the etch stop layer 130 can be relatively small because of the thickness of the etch stop layer 130, which is placed at least in the direction of the y-axis in the first region 130_1. Thus, the major stress, which is the Y direction stress, to increase the mobility of the major carrier of the NMOS transistor is transferred to the first gate electrode 114_1 with a relatively high efficiency. The Y direction stress delivered to the first gate electrode 114_1 with a relatively high efficiency is stored with the recrystallization of the first gate electrode 114_1 and sufficiently increases the electron mobility in the channel.

In contrast, in the PMOS transistor region II, stress is not stored in the second gate electrode 114_2 and the second source/drain regions 102_2 after recrystallization during the thermal treatment process because the tensile stress layer 142 is removed. As illustrated using Table 1, in the PMOS transistor region II, when stress caused by a tensile stress layer is introduced, the mobility of the major carrier (hole) is decreased. However, because stress is not stored in the PMOS transistor region II, the mobility of the major carrier is not decreased.

Due to the recrystallization, a semiconductor device with improved NMOS transistor characteristics may be provided.

Referring to FIG. 6H, optionally, the tensile stress layer 142 that covers the NMOS transistor region I is removed. The removal of the tensile stress layer 142 can be performed with a wet etch or other methods. Although the tensile stress layer 142 is removed, stress (the tensile stress in the directions of the x-axis and the z-axis and the compressive stress in the direction of the y-axis) caused by the tensile stress layer 142 is stored in the first gate electrode 114_1 and the first source/drain 102_1 of the NMOS transistor region I, and in the NMOS transistor channel to improve the electron mobility can be provided. Therefore, the electron mobility of the NMOS transistor can be maintained at about the same level even after the tensile stress layer 142 is removed.

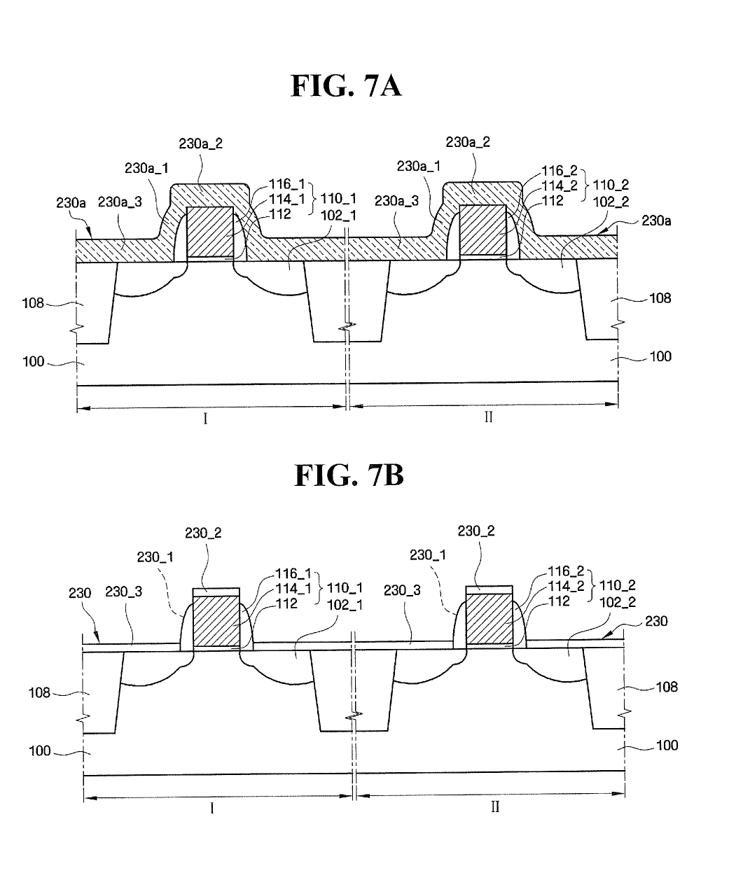

Also, optionally, the removal of the etch stop layer 130 can be performed at the same time as this operation or after this operation. Also, not shown in the drawings, a successive process of forming a metal silicide layer by performing a salicide process on the surface of the first gate electrode 114_1, the first source/drain regions 102_1, the second gate electrode 114_2, and the source/drain regions 102_2 may be performed. Also, forming an interlayer dielectric layer on the NMOS transistor and the PMOS transistor, forming a contact inside the interlayer dielectric layer, and forming a wire on the interlayer dielectric layer can be performed. FIGS. 7A through 7B are sectional views illustrating methods of fabricating a semiconductor device according to further embodiments of the present invention. These figures illustrate exemplary methods of implementing the structure illustrated in FIG. 4.

First, using the same methods described with reference to FIGS. 6A through 6C, an NMOS transistor is formed in a NMOS transistor region I of a semiconductor substrate 100, and a PMOS transistor is formed in a PMOS transistor region II of the semiconductor substrate 100. Next, referring to FIG. 7A, a preliminary etch stop layer 230a is formed on the entire semiconductor substrate 100. Formation of the preliminary etch stop layer 230a is formed in substantially the same manner as that illustrated in the operations of FIG. 6D. The preliminary etch stop layer 230a is formed to include a first region 230a_1 on first and second spacers 116_1, 116_2, a second region 230a_2 on first and second gate electrodes 114_1, 114_2, and a third region 230a_3 on first and second source/drain regions 102_1, 102_2 and to have a thickness of the first region 230a_1 to be less than the thicknesses of the second region 230a_2 and the third region 230a_3. In some embodiments, the preliminary etch stop layer 230a is formed to be a thicker layer than the etch stop layer 130 formed in the step of FIG. 6C.

Referring to FIG. 7B, the preliminary etch stop layer 230a is isotropically etched using a method including a wet etch process. Due to the isotropic etch process, the thickness of the preliminary etch stop layer 230a is reduced regardless of regions including the first region 230a_1, the second region 230a_2, and the third region 230a_3. As a result, a completed etch stop layer 230 has a smaller thickness ratio of the first region 230_1 to the second region 230_2 and the third region 230_3 as compared to the thickness ratio in the case of the preliminary etch stop layer 230a.

In some embodiments of the present invention, the relatively thin first region 230_1 is removed, and the relatively thick second region 230_2 and third region 230_3 remain with a thickness to provide functionality as the etch stop layer 230. For example, if the thickness of the second region 230a_2 and the third region 230a_3 of the preliminary etch stop layer 230a is about 500 Å, and the thickness of the first region 230a_1 is about 80% that of the 500 Å, which is 400 Å, the thicknesses of the second region 230_2 and the third region 230_3 of the complete etch stop layer 230, which is finished by an isotropic etch process, can be about 100 Å, and the thickness of the first region 230_1 can be 0.

Except for the reduction of the thickness of the first region 230_1 of the etch stop layer 230 or the removal of the first region 230_1, the successive process is substantially identical to the process described using FIGS. 6D through 6G.

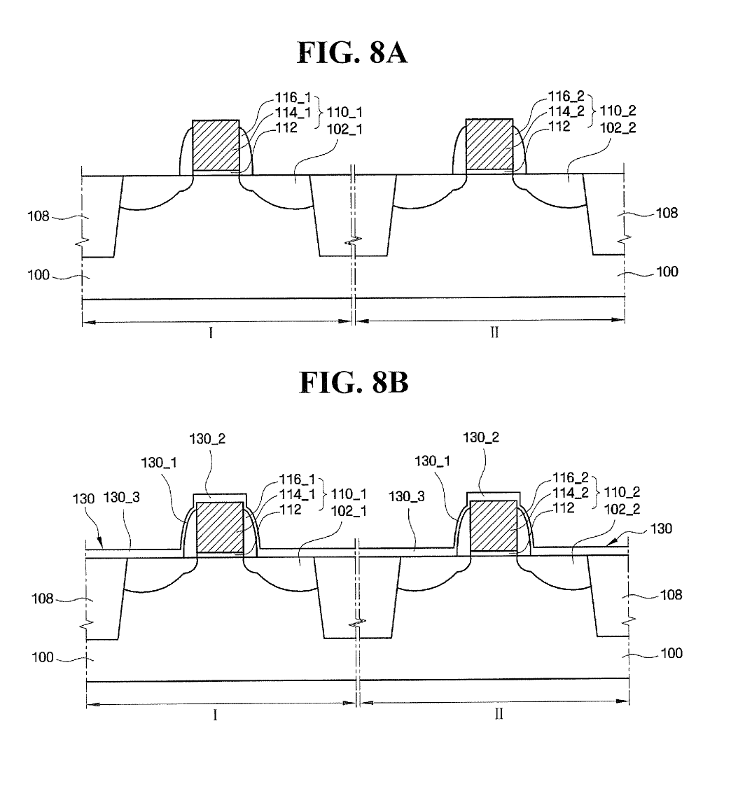

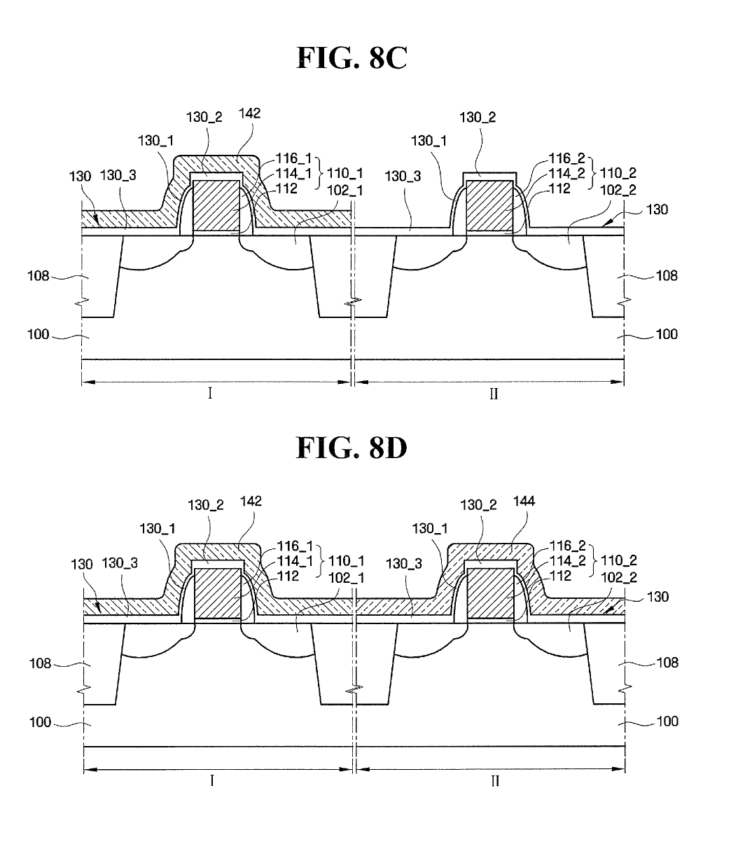

FIGS. 8A through 8D are sectional views illustrating methods of fabricating a semiconductor device according to further embodiments of the present invention. FIGS. 8A through 8D illustrate a case where stress is provided to a channel by a stress layer without applying a stress memorization technique.

Referring to FIG. 8A, a first source/drain region 102_1 is formed in a NMOS transistor region I of a semiconductor substrate 100 and a PMOS transistor is formed in a PMOS transistor region I of the semiconductor substrate 100. Except for the ion implantation of amorphization material, this operation is performed with substantially the same method as described above with reference to FIGS. 6A through 6C.

Referring to FIG. 8B, an etch stop layer 130 is formed on the entire surface of the resulting structure of FIG. 8A using substantially the same method as described with reference to FIG. 6D.

Referring to FIG. 8C, a tensile stress layer 142 is formed on the etch stop layer 130 and is patterned. During the patterning, the etch stop layer 130 provides etch stop functionality. As a result of the patterning, a tensile stress layer 142 remains only on the NMOS transistor region I and covers the first gate structure 110_1 and the first source/drain regions 102_1. Therefore, the electron mobility is improved by providing tensile stress in the direction of an x-axis and a z-axis of the NMOS transistor, and compressive stress in the direction of the y-axis of the NMOS transistor. Here, the thickness of a first region 130_1 of the etch stop layer 130 placed in the direction of the y-axis is relatively small, and, as described above, the stress may be transferred effectively. This operation can be replaced by the method described with reference to FIGS. 7A and 7B.

Compared to the exemplary embodiments in FIGS. 6A through 6G, because the embodiments of FIGS. 8A-8C do not include an operation to store stress in a first gate electrode 114_1 and the first source/drain regions 102_1, the tensile stress 142 is not removed in the successive process.

Referring to FIG. 8D, a compressive stress layer is formed on the entire surface of the structure of FIG. 8C and patterning is performed to selectively remove the compressive stress layer on the NMOS transistor region I. As a result, a compressive stress layer 144 remains only on the PMOS transistor region II, and covers a second gate structure 110_2 and second source/drain regions 102_2.

The order of forming the tensile stress layer 142 and the compressive stress layer 144 can be changed. Also, instead of the etch stop layer 130 in FIG. 8C, or in addition to the etch stop layer 130 in FIG. 8C, an etch stop layer (not shown) can be formed between the tensile stress layer 142 and the compressive stress layer 144. Also, forming the compressive stress layer 144 can be omitted in some embodiments.

According to some embodiments of the present invention, although an etch stop layer is formed on an NMOS transistor and a stress layer is formed on the etch stop layer, the etch stop layer which lies in between the stress layer in the major direction to increase the electron mobility and the NMOS transistor can be minimized or may be omitted. Thus, sufficient stress can be delivered to the NMOS transistor.

While the present invention has been particularly shown and described with reference to exemplary embodiments thereof, it will be understood by those of ordinary skill in the art that various changes in form and details may be made therein without departing from the spirit and scope of the present invention as defined by the following claims.

That which is claimed:

1. A semiconductor device, comprising:
a semiconductor substrate;
a gate structure formed on the semiconductor substrate, the gate structure including a gate electrode formed on the semiconductor substrate and spacers formed on sidewalls of the gate electrode;
source/drain regions formed in the semiconductor substrate on both sides of the gate structure; and
an etch stop layer formed on the gate structure and including a first region formed on the spacers and a second region formed on the gate electrode, wherein a thickness of the first region is about 85% that of a thickness of the second region or less.

2. The semiconductor device of claim 1, wherein the etch stop layer includes a third region extended onto the source/drain regions, and the thickness of the first region is about 85% that of a thickness of the third region or less.

3. The semiconductor device of claim 1, further comprising a tensile stress layer that covers the etch stop layer.

4. The semiconductor device of claim 3, wherein the gate structure and the source/drain regions are included in an NMOS transistor.

5. The semiconductor device of claim 1, wherein the etch stop layer is formed of a PE-TEOS layer.

6. The semiconductor device of claim 1, wherein the thickness of at least a part of the first region is about 0.

7. The semiconductor device of claim 1, wherein the gate electrode and the source/drain regions comprise an amorphization material comprising Ge, X, C, and/or F.

8. A semiconductor device, comprising:
a semiconductor substrate including an NMOS transistor region and a PMOS transistor region;
a first gate structure formed in the NMOS transistor region on the semiconductor substrate, the first gate structure including a first gate electrode formed on the semiconductor substrate and first spacers formed on sidewalls of the first gate electrode;
first source/drain regions formed in the semiconductor substrate on both sides of the first gate structure;
a second gate structure formed in the PMOS transistor region on the semiconductor substrate, the second gate structure including a second gate electrode formed on the semiconductor substrate and second spacers formed on sidewalls of the second gate electrode;
second source/drain regions formed in the semiconductor substrate on both sides of the second gate structure; and
an etch stop layer formed on the first gate structure and the second gate structure and including a first region formed on the first spacers and the second spacers and a second region formed on the first gate electrode and the second gate electrode, wherein a thickness of the first region is about 85% that of a thickness of the second region or less.

9. The semiconductor device of claim 8, wherein the etch stop layer includes a third region extended onto the first and second source/drain regions, and the thickness of the first region is about 85% that of a thickness of the third region or less.

10. The semiconductor device of claim 8, further comprising a tensile stress layer that covers the first gate structure formed on the NMOS transistor region and the etch stop layer.

11. The semiconductor device of claim 10, further comprising a compressive stress layer that covers the second gate structure formed on the PMOS transistor region and the etch stop layer.

12. The semiconductor device of claim 8, wherein the etch stop layer is formed of a PE-TEOS layer.

13. The semiconductor device of claim 8, wherein the thickness of at least a part of the first region is about 0.

14. The semiconductor device of claim 8, wherein the gate electrode and the source/drain regions comprise an amorphization material comprising Ge, X, C, and/or F.

15. A method of fabricating a semiconductor device, comprising:
providing a semiconductor substrate;
forming a gate structure on the semiconductor substrate, the gate structure including a gate electrode formed on the semiconductor substrate and spacers formed on sidewalls of the gate electrode;
forming source/drain regions on both sides of the gate structure;
forming an etch stop layer on the gate structure, which includes a first region formed on the spacers and a second region formed on the gate electrode, wherein a thickness of the first region is about 85% of a thickness of the second region or less; and
forming a tensile stress layer on the etch stop layer.

16. The method of claim 15, wherein the etch stop layer includes a third region extended onto the source/drain regions, and the thickness of the first region is about 85% that of a thickness of the third region or less.

17. The method of claim 15, wherein the etch stop layer is formed using PECVD.

18. The method of claim 15, wherein forming the etch stop layer includes forming a preliminary etch stop layer on the gate structure and etching the preliminary etch stop layer isotropically, wherein the second region remains, and at least part of the first region is completely removed.

19. The method of claim 15, further comprising amorphizing the gate electrode and recrystallizing the amorphized first gate electrode after forming the tensile stress layer.

20. The method of claim 19, wherein amorphizing comprises ion implanting amorphization ions including comprising Ge, X, C, and/or F to the gate electrode, and recrystallizing comprises thermal treatment of the amorphizied gate electrode.

21. A method of fabricating a semiconductor device, comprising:
providing a semiconductor substrate including an NMOS transistor region and a PMOS transistor region;
forming a first gate structure in the NMOS transistor region on the semiconductor substrate, the first gate structure including a first gate electrode formed on the semiconductor substrate and first spacers formed on sidewalls of the first gate electrode and a second gate structure in the PMOS transistor region on the semiconductor substrate, the second gate structure including a second gate electrode formed on the semiconductor substrate and second spacers formed on sidewalls of the second gate electrode;
forming first source/drain regions on both sides of the first gate structure and second source/drain regions on both sides of the second gate structure;
forming an etch stop layer on the first gate structure and the second gate structure, including a first region formed on the first spacers and the second spacers, and a second region formed on the first gate electrode and the second gate electrode, wherein a thickness of the first region is about 85% of a thickness of the second region or less; and
forming a tensile stress layer on the etch stop layer.

22. The method of claim 21, wherein the etch stop layer includes a third region extended onto the first and second source/drain regions, and the thickness of the first region is about 85% of a thickness of the third region or less.

23. The method of claim 21, wherein the etch stop layer is formed using PECVD.

24. The method of claim 21, wherein forming the etch stop layer comprises forming a preliminary etch stop layer on the first gate structure and the second gate structure, and isotropically etching the preliminary etch stop layer, wherein the second region remains and at least part of the first region is completely removed.

25. The method of claim 21, further comprising amorphizing the first gate electrode and the second gate electrode, and recrystallizing the amorphized first gate electrode and the amorphized second gate electrode after forming the tensile stress layer.

26. The method of claim 25, wherein amorphizing comprises ion implanting amorphization ions comprising Ge, X, C, and/or F to the first gate electrode and the second gate electrode, and recrystallizing comprises thermal treatment of the amorphized first gate electrode and the amorphizied second gate electrode.

27. The method of claim 26, further comprising selectively removing the tensile stress layer on the PMOS transistor region before recrystallizing.

28. The method of claim 21, further comprising selectively removing the tensile stress layer in the PMOS transistor region, forming a compressive stress layer on the tensile stress layer in the NMOS transistor region and the etch stop layer in the PMOS region, and
selectively removing the compressive stress layer in the NMOS transistor region.
